(19) United States
(12) Patent Application Publication
(10) Pub. No.: US 2025/0054727 A1
(43) Pub. Date: Feb. 13, 2025

(54) BEAM POSITION MEASUREMENT METHOD AND CHARGED PARTICLE BEAM WRITING METHOD

(71) Applicant: NuFlare Technology, Inc., Yokohama-shi (JP)

(72) Inventors: Tsubasa NANAO, Yokohama-shi (JP); Osamu IIZUKA, Yokohama-shi (JP)

(73) Assignee: NuFlare Technology, Inc., Yokohama-shi (JP)

(21) Appl. No.: 18/760,092

(22) Filed: Jul. 1, 2024

(30) Foreign Application Priority Data
Aug. 8, 2023 (JP) 2023-129380

(51) Int. Cl. H01J 37/304; H01J 37/147; H01J 37/317

(52) U.S. Cl. CPC H01J 37/3045; H01J 37/1471; H01J 37/3177; H01J 2237/24578

(57) ABSTRACT

In one embodiment, a beam position measurement method includes scanning a mark with a charged particle beam in each of conditions, the mark being provided on a stage on which a substrate is placed, and measuring a beam irradiation position based on electrons reflected from the mark, scanning the mark in a reference condition, measuring a beam irradiation position based on electrons reflected from the mark, and calculating a drift amount based on an obtained result of measurement of the beam irradiation position in the reference condition, and correcting the beam irradiation position measured in each of the conditions, using the drift amount.

### CROSS REFERENCE TO RELATED APPLICATION

This application is based upon and claims benefit of priority from the Japanese Patent Application No. 2023-129380, filed on Aug. 8, 2023, the entire contents of which are incorporated herein by reference.

### FIELD

The present invention relates to a beam position measurement method and a charged particle beam writing method.

### BACKGROUND

With high integration of LSI, the circuit line width of semiconductor devices has been further miniaturized. An electron beam writing technique with a superior resolution is used as a method of forming an exposure mask (the one used in a stepper or a scanner is also called a reticle) for forming a circuit pattern on these semiconductor devices.

In an electron beam writing apparatus, a desired position on a substrate is irradiated with an electron beam by controlling the voltage applied to a deflector to adjust the amount of deflection of the electron beam. In order to maintain the irradiation position of the electron beam on the substrate with high precision, it is important to accurately determine the deflection sensitivity. For this reason, the beam irradiation positions with multiple different deflection voltages are measured while changing the deflection voltage, and deflection sensitivity is calculated. The beam position can be measured by scanning a mark placed on a stage with a beam, and detecting reflected electrons.

As an electron beam writing apparatus, a writing apparatus using a multi-beam is being developed. Many beams can be radiated using a multi-beam, as compared to when writing is performed with a single electron beam, thus the throughput can be significantly improved. In a multi-beam writing apparatus, a multi-beam is formed by passing an electron beam emitted from e.g., an electron source through a shaping aperture array substrate provided with a plurality of openings, blanking control of each beam is performed, and the beam not blocked by a limiting aperture member is emitted to the substrate.

In a multi-beam writing apparatus, a plurality of beams are emitted at a time, and a desired figure shape pattern is written by connecting the beams formed by passing through the same opening or different openings of a shaping aperture array substrate. Thus, the shape (beam array shape) of the entire image of the multi-beam emitted on the substrate reflects the stitching accuracy of a written figure.

It is important to accurately grasp the beam array shape to maintain high accuracy of writing using the multi-beam. Thus, a process of setting only the beams in a partial region on and measuring the beam position by scanning the mark with an on-beam is performed on the entire surface while changing the beam region to measure the beam array shape.

In an electron beam writing apparatus, organic matters adhere onto an aperture member that cuts the beam, such as a limiting aperture member, and an electric charge accumulates due to the beam which had been cut by the member, thus beam position variation (drift) may occur. When such a beam position variation occurs, the deflection sensitivity and the beam array shape cannot be measured accurately, thus the writing accuracy may deteriorate.

### BRIEF DESCRIPTION OF THE DRAWINGS

FIG. 1 is a schematic diagram of a multi-charged particle beam writing apparatus according to an embodiment of the present invention.

FIG. 2 is a schematic view of a shaping aperture array substrate.

FIG. 3 is a plan view of a reflection mark.

FIG. 4 is a flow chart for explaining a beam array shape measurement method.

FIG. 5 is a view for explaining a method of measuring a beam array shape.

FIG. 6 is a view illustrating an example of a beam array shape to be calculated.

FIG. 7 is a diagram illustrating an example of timing for beam position measurement in a reference condition.

FIG. 8 is a flow chart for explaining a method of calculating a beam array shape.

### DETAILED DESCRIPTION

According to one embodiment of the present invention, a beam position measurement method includes scanning a mark with a charged particle beam in each of conditions, the mark being provided on a stage on which a substrate is placed, and measuring a beam irradiation position based on electrons reflected from the mark, scanning the mark in a reference condition, measuring a beam irradiation position based on electrons reflected from the mark, and calculating a drift amount based on an obtained result of measurement of the beam irradiation position in the reference condition, and correcting the beam irradiation position measured in each of the conditions, using the drift amount.

Hereinafter, an embodiment of the present invention will be described with reference to the drawings. In this embodiment, a configuration using an electron beam as an example of a charged particle beam will be described. However, the charged particle beam is not limited to the electron beam, and may be another charged particle beam such as an ion beam.

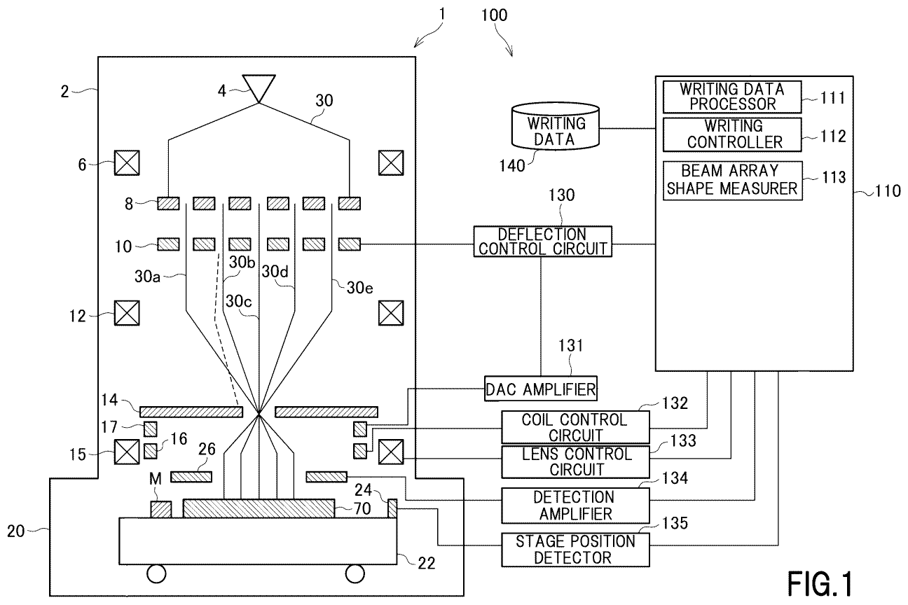

FIG. 1 is a conceptual diagram illustrating the configuration of a writing apparatus in this embodiment. In FIG. 1, the writing apparatus includes a writer 1 and a controller 100. The writing apparatus is an example of a multi-charged particle beam writing apparatus. The writer 1 includes a column 2 and a writing chamber 20. In the column 2, an electron source 4, an illumination lens 6, a shaping aperture array substrate 8, a blanking aperture array substrate 10, a reduction lens 12, a limiting aperture member 14, an objective lens 15, a coil 16, a main deflector 17 (deflector), and a sub deflector (not illustrated) are disposed.

In the writing chamber 20, an XY stage 22 and a detector 26 are disposed. A substrate 70 serving as a writing target is disposed on the XY stage 22. The substrate 70 includes an exposure mask when a semiconductor device is fabricated, and a semiconductor substrate (silicon wafer) on which a semiconductor device is fabricated. The substrate 70 includes a mask blank coated with resist and nothing has been written thereon.

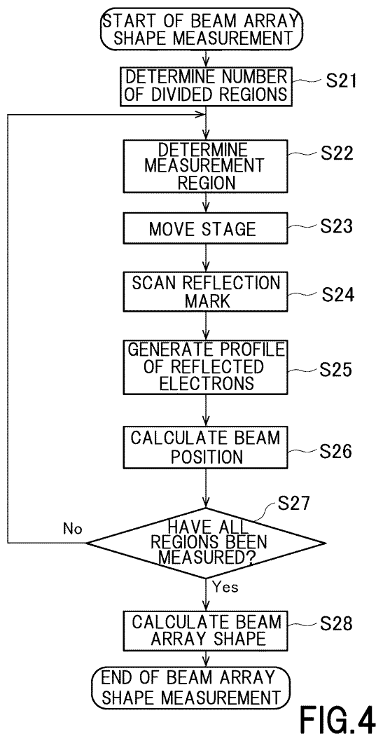

A mirror 24 for measurement of the position of the XY stage 22 is disposed on the XY stage 22. The XY stage 22 is provided thereon with a metal reflection mark M for beam calibration. The reflection mark M has e.g., a cross shape so that its position is easily detected by scanning with an electron beam (see FIG. 3). The detector 26 detects reflected electrons from the reflection mark M when the cross of the reflection mark M is scanned with an electron beam.

The controller 100 includes a control computer 110, a deflection control circuit 130, digital-analog conversion (DAC) amplifier 131, a coil control circuit 132, a lens control circuit 133, a detection amplifier 134, a stage position detector 135, and a storage device 140 such as a magnetic disk drive.

The deflection control circuit 130, the coil control circuit 132, the lens control circuit 133, the detection amplifier 134, the stage position detector 135, and the storage device 140 are connected to the control computer 110 via a bus. Writing data is input from the outside, and stored in the storage device 140.

The deflection control circuit 130 is connected to the DAC amplifier 131. The DAC amplifier 131 is connected to the main deflector 17. The coil control circuit 132 is connected to the coil 16. The lens control circuit 133 is connected to the objective lens 15.

The control computer 110 has the functions of a writing data processor 111, a writing controller 112 and a beam array shape measurer 113. The function of each component of the control computer 110 may be implemented by hardware, or implemented by software. When the function is implemented by software, a program to implement at least part of the function of the control computer 110 may be stored in a recording medium, and a computer including an electric circuit may read and execute the program. The recording medium is not limited to a detachable medium such as a magnetic disk and an optical disk, and may be a fixed recording medium such as a hard disk drive and a memory.

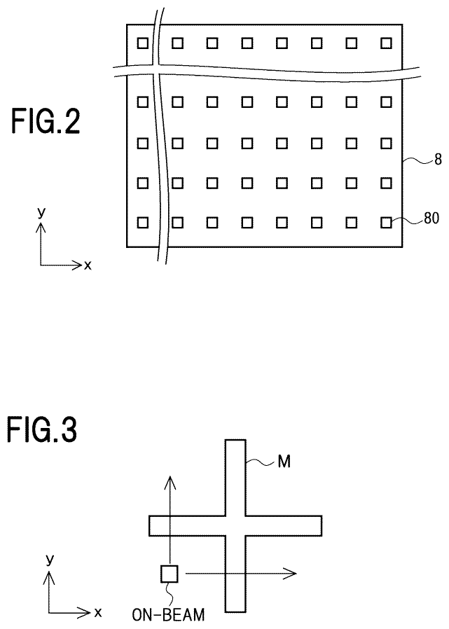

FIG. 2 is a conceptual diagram illustrating the configuration of the shaping aperture array substrate 8. As illustrated in FIG. 2, in the shaping aperture array substrate 8, a plurality of openings 80 are formed in a matrix in a vertical direction (y direction) and in a horizontal direction (x direction) with a predetermined arrangement pitch. The openings 80 are formed as rectangles having the same dimensional shape. Alternatively, the openings 80 may be circles with the same diameter.

An electron beam 30 emitted from the electron source 4 illuminates the shaping aperture array substrate 8 in its entirety substantially perpendicularly by the illumination lens 6. The electron beam 30 illuminates a region including the plurality of openings 80 of the shaping aperture array substrate 8. Multi-beams 30a to 30e as illustrated in FIG. 1 are formed by passing part of the electron beam 30 through the plurality of openings 80.

Passage holes (openings), through which the beams in the multi-beam pass, are formed in the blanking aperture array substrate 10 at positions corresponding to the openings 80 of the shaping aperture array substrate 8 illustrated in FIG. 2. A blanking deflection electrode (blanker, that is a blanking deflector) to deflect a beam is disposed in the vicinity of each passage hole.

The electron beams 30a to 30e passing through respective passage holes are each deflected independently by a voltage applied to a corresponding blanker. Blanking control is performed by the deflection.

In this manner, a plurality of blankers perform blanking control on corresponding beams in the multi-beams passing through the plurality of openings 80 of the shaping aperture array substrate 8.

The multi-beams 30a to 30e which have passed through the blanking aperture array substrate 10 are each reduced in beam size and arrangement pitch by the reduction lens 12, and travel to an opening formed in the center of the limiting aperture member 14. An electron beam deflected by a blanker of the blanking aperture array substrate 10 is deviated from the original trajectory, and displaced from the opening in the center of the limiting aperture substrate 14, and blocked by the limiting aperture member 14. In contrast, an electron beam not deflected by any blanker of the blanking aperture array substrate 10 passes through the opening in the center of the limiting aperture member 14.

The limiting aperture member 14 blocks each electron beam which has been deflected by a blanker of the blanking aperture array substrate 10 to achieve beam OFF state.

The multi-beams 30a to 30e which have passed through the limiting aperture member 14 are adjusted in alignment by the coil 16, focused by the objective lens 15, and form a pattern image on the substrate 70 with a desired reduction factor. The main deflector 17 collectively deflects the electron beams (the entire multi-beams) which have passed through the limiting aperture member 14 in the same direction, and emits the beams to a writing position (irradiation position) on the substrate 70.

When the XY stage 22 is continuously moved, tracking control is performed by the main deflector 17 so that the writing position (irradiation position) of the beam follows the movement of the XY stage 22. The position of the XY stage 22 is measured using reflected light of a laser beam which has been emitted from the stage position detector 135 to the mirror 24 on the XY stage 22.

The multi-beams emitted at one time are ideally arranged with the pitch which is the product of the arrangement pitch of the plurality of openings 80 of the shaping aperture array 8 and the above-mentioned desired reduction factor. The writing apparatus performs a writing operation by a raster scan method for irradiating with a shot beam consecutively and sequentially, and when a desired pattern is written, control the beams needed according to the pattern at beam ON by the blanking control.

The writing data processor 111 of the control computer 110 reads writing data from the storage device 140, and performs multi-stage data conversion to generate shot data. The shot data defines the presence or absence of irradiation and irradiation time for each of a plurality of lattice-shaped irradiation regions into which a writing surface of the substrate 70 is divided with e.g., beam size.

The writing controller 112 outputs a control signal to the deflection control circuit 130 based on the shot data and stage position information. The deflection control circuit 130 controls the voltage applied to each blanker of the blanking aperture array substrate 10 based on the control signal. In addition, the deflection control circuit 130 calculates deflection amount data (tracking deflection data) for beam deflection to follow the movement of the XY stage 22. The tracking deflection data which is a digital signal is output to the DAC amplifier 131 that converts the digital signal to an analog signal, amplifies the analog signal, and applies the analog signal to the main deflector 17 as a tracking deflection voltage.

In a multi-beam writing apparatus, the substrate 70 as a writing target is irradiated with a large number of beams at one time, which are arranged with a pitch obtained by multiplying the arrangement pitch of the plurality of openings 80 of the shaping aperture array substrate 8 by a predetermined reduction factor, then a desired figure shape pattern is written by connecting the beams to eliminate the beam pitch. Thus, before the writing process or during the writing process, it is necessary to detect the beam position, measure the beam array shape to adjust the dimensions thereof, and modulate the irradiation amount of each beam.

The writing apparatus according to this embodiment measures the beam array shape using the mark for position measurement. As the mark for position measurement, it is possible to use a transparent mark provided on the stage for allowing the multi-beams to pass through one at a time to measure the position, and a reflection mark provided on the stage or the mask substrate to measure reflected electrons. In this embodiment, the configuration using a reflection mark M provided on the XY stage 22 as the mark for position measurement will be described. The reflection mark M is e.g., the cross shape as illustrated in FIG. 3. Only the beams in a partial region are set on, the on-beams are deflected forward, backward, rightward, leftward (in x direction and y direction) by the main deflector 17 to scan the cross of the reflection mark M, reflected electrons are detected by the detector 26, amplified by the detection amplifier 134, and converted to digital data, then measurement data is output to the control computer 110.

The beam array shape measurer 113 calculates the position (the center of the on-beam region) of the beam from a profile (change in the intensity of the reflected electrons) in which the measured reflected electrons are arranged in time series, and the stage position at that time. The beam array shape measurer 113 measures a beam array shape from the beam position of each on-beam region. A method for measuring a beam array shape will be described with reference to the flowchart illustrated in FIG. 4.

The blanking aperture array substrate 10 is divided into a plurality of measurement regions, and the reflection mark M is scanned with a beam corresponding to each measurement region. In other words, the shaping aperture array substrate 8 is divided into a plurality of measurement regions, and the beam which has passed through the openings 80 of each measurement region is set on to scan the reflection mark M.

First, the number n (n is an integer greater than or equal to 2) of divided regions of the blanking aperture array substrate 10 is determined (step S21). The reason why the blanking aperture array substrate 10 (the shaping aperture array substrate 8) is divided into a plurality of measurement regions is to measure distortion for each region of the shaping aperture array substrate 8. The maximum deflection amount of the main deflector 17 used for beam scan is not large enough to cover the entire region of the blanking aperture array substrate 10, thus the deflection amount used for measurement is preferably small enough causing no distortion in the beam array shape.

A region which has not been measured yet is selected to determine the measurement region (step S22). The XY stage 22 is moved, and the reflection mark M is placed at the position right below the beam for the measurement region (step S23).

For example, the voltage applied to the blanker of the measurement region is set to 0 V, and the voltage applied to the blankers of other regions (non-measurement region) is set to 5 V. A plurality of beams set to beam on by the blanker of the measurement region are deflected by the main deflector 17 in the XY direction to scan the reflection mark M, and the detector 26 detects reflected electrons (step S24).

The control computer 110 generates a profile (change in the intensity of the reflected electrons) in which the reflected electrons detected by the detector 26 are arranged in time series (step S25).

The beam array shape measurer 113 calculates the beam position (the central coordinates of the on-beam region) corresponding to the measurement region using the stage position detected by the stage position detector 135 (step S26).

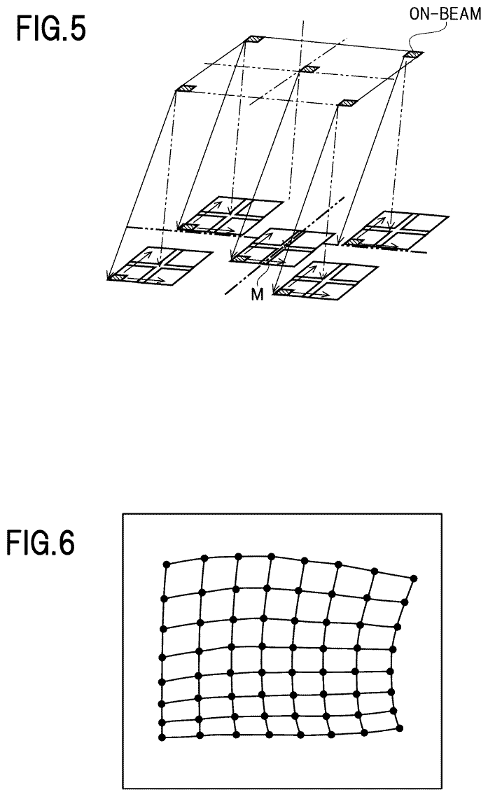

Such movement of the stage, scanning of the reflection mark M, and on-beam position calculation are performed for all of n measurement regions of the blanking aperture array substrate 10 (steps S22 to S27). FIG. 5 illustrates an example in which in response to a change in the measurement region, the XY stage 22 is moved, and the reflection mark M is placed at the position right below the beam for the measurement region.

After completion of measurement for all measurement regions (step S27_Yes), the beam array shape measurer 113 calculates the beam array shape based on the beam position of each measurement region (step S28). For example, the beam array shape measurer 113 performs fitting with a three-degree polynomial for the central coordinates of on-beam regions corresponding to the n measurement regions to determine a polynomial that represents the beam array shape. When the polynomial is plotted as a graph, for example, the beam array shape as illustrated in FIG. 6 is obtained. FIG. 6 illustrates a beam array shape in a visually recognizable manner by setting an ideal lattice and plotting displacement from the ideal lattice.

In a writing apparatus, organic matters adhere onto an aperture member that cuts the beam, such as the limiting aperture member 14, and an electric charge accumulates due to the beam which had been cut by the member, thus beam position variation (drift) occurs. Thus, it is preferable to calculate the beam array shape by measuring the beam position variation amount and correcting the beam position measurement result.

For example, the beam position is measured regularly in a reference condition, and the amount of position change (the drift amount) is determined. The beam position used for beam array shape calculation is corrected based on the determined amount of position change. The beam position measurement in the reference condition is, for example, measurement of the position of the central beam. Only one or a plurality of beams located in the center of the blanking aperture array substrate 10 (the shaping aperture array substrate 8) are set on, the reflection mark M is scanned with the on-beams, and the beam position is measured from a result of detection of reflected electrons. The difference between the result of measurement and a designed value (ideal value) is determined as the drift amount.

Because the variation in the drift is high immediately after the start of measurement (writing), the interval of beam position measurement (drift measurement) in the reference condition is decreased. After the drift is reduced with the lapse of time, the interval of drift measurement is increased. Thus, reduction in the throughput can be avoided.

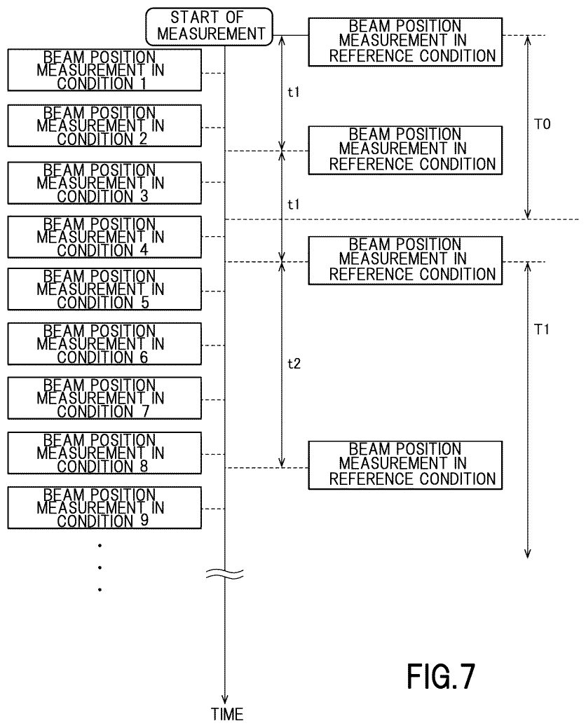

FIG. 7 illustrates an example of timing for beam position measurement (drift measurement) in the reference condition, and for beam position measurement in condition 1 to condition n. The condition 1 to the condition n have different on-beam regions.

Immediately after the start of measurement (writing), drift measurement is performed with a first drift measurement interval t1. Specifically, the beam position is measured in the reference condition every lapse of time t1 to determine the drift amount.

The beam position measurement result in the condition 1 to condition n is corrected based on the drift amount determined most recently. For example, the beam position measurement result in the condition 3 of FIG. 7 is corrected using the drift amount measured at time t1. Similarly, the beam position measurement result in the condition 5 is corrected using the drift amount measured at time 2×t1.

The drift amount to be used for correction of the beam position measurement result in the condition 1 to the condition n may be calculated by interpolation using the drift amounts determined by drift measurements before and after the current time. For example, a drift amount at the time of beam position measurement in the condition 2 is estimated by interpolation using the drift amount measured at time t0 and the drift amount measured at time t1, and the beam position measurement result in the condition 2 is corrected using the estimated drift amount.

The drift amount at the time of beam position measurement in the condition 1 to the condition n may be estimated by extrapolation instead of interpolation.

After lapse of a measurement interval change time T0 (T0>t1), the measurement interval for drift measurement is increased, and drift measurement is performed with a second drift measurement interval t2 (t2>t1). After further lapse of time, the drift measurement interval may be changed from t2 to t3 (t3>t2). In addition, the measurement interval change time may be gradually changed (updated) from T0 to T1, T2, (T0<T1<T2<,..).

The beam array shape can be determined by correcting the beam position measurement result in the condition 1 to the condition n by the drift amount, and performing polynomial fitting. Instead of correcting the beam position measurement result by the drift amount, the deflection position may be corrected by the drift amount to scan the reflection mark M at the time of beam position measurement in the condition 1 to the condition n.

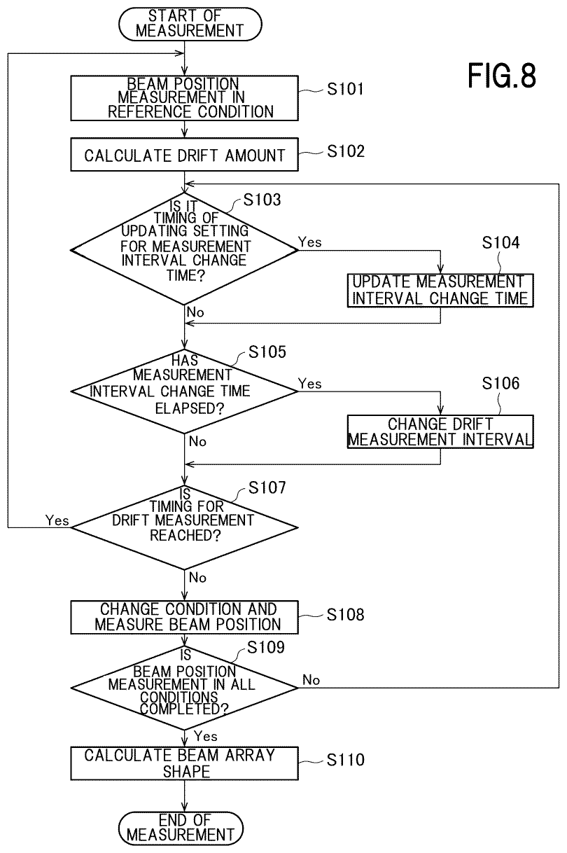

FIG. 8 is a flow chart for explaining a method of calculating a beam array shape while updating the setting for the drift measurement interval and the measurement interval change time.

The beam position is measured in the reference condition, and the drift amount is calculated (step S101, S102).

At the timing of updating the setting for the measurement interval change time (step S103_Yes), the measurement interval change time is updated (step S104). For example, the measurement interval change time is updated from T0 to T1. The timing of updating the setting for the measurement interval change time is arbitrary, and may be after lapse of a predetermined time or a predetermined number of times of drift measurement.

When the measurement interval change time has elapsed (step S105_Yes), the drift measurement interval is changed (step S106). For example, the drift measurement interval is changed from t1 to t2.

When the time of the drift measurement interval has elapsed since the last drift measurement, and the timing for drift measurement is reached (step S107_Yes), the drift measurement is performed (step S101, S102). For example, when time t1 has elapsed since the first drift measurement (beam position measurement in the reference condition) illustrated in FIG. 7, the second drift measurement is performed.

The beam position measurement is performed in the condition changed (the on-beam region is changed) (step S108). The beam position measurement result is corrected using the drift amount determined in the most recent drift measurement.

Steps S101 to S108 are repeated until the beam position measurement is performed in all conditions (the conditions 1 to n).

When the beam position measurement in all conditions is completed (step S109_Yes), the beam array shape is calculated based on the beam position measurement result corrected using the drift amount (step S110).

In this manner, according to this embodiment, it is possible to accurately measure the beam position, and determine the beam array shape with high accuracy while avoiding reduction in the throughput. A desired pattern can be written with high accuracy by correcting beam irradiation conditions based on the determined beam array shape so that distortion of the beam array shape causes no effect, the beam irradiation conditions including the irradiation amount of each beam, the position and dimensions of a pattern to be written, and the electron optical conditions for the beam.

In the above embodiment, an example has been described in which the measurement interval for drift measurement is changed when the measurement interval change time has elapsed; however, the measurement interval may be changed when drift measurement is performed for a predetermined number of times.

A table in which the measurement interval and the measurement frequency are set in advance may be created, and measurement may be performed based on the table.

In the above embodiment, the measured drift amount is used for the beam position correction at the time of beam array shape measurement, but may be used for beam position correction at the time of measurement of deflection sensitivity of the main deflector 17 and the sub deflector. The beam position is measured with multiple deflection voltages while changing the deflection voltage, and the deflection sensitivity (the rate of variability in deflection distance with respect to the deflection voltage) is determined by correcting the beam position measurement result by the drift amount. In the beam position measurement (drift measurement) in the reference condition, for example, the deflection amount (deflection voltage) is set to zero. The deflection range is then identified based on the determined deflection sensitivity.

In the above embodiment, an example has been described in which a multi-beam writing apparatus is used as an electron beam writing apparatus; however, the present invention is applicable to correction of the deflection sensitivity of a single beam writing apparatus.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A beam position measurement method comprising:
scanning a mark with a charged particle beam in each of conditions, the mark being provided on a stage on which a substrate is placed, and measuring a beam irradiation position based on electrons reflected from the mark;
scanning the mark in a reference condition, measuring a beam irradiation position based on electrons reflected from the mark, and calculating a drift amount based on an obtained result of measurement of the beam irradiation position in the reference condition; and
correcting the beam irradiation position measured in each of the conditions, using the drift amount.

2. The beam position measurement method according to claim 1,
wherein the conditions are for a beam position or a deflection voltage of the charged particle beam.

3. The beam position measurement method according to claim 1,
wherein measurement of the drift amount is performed at a predetermined measurement interval or a predetermined measurement frequency, or performed after exceeding a predetermined measurement time or a predetermined number of times of measurement with the measurement interval or the measurement frequency which has been changed.

4. The beam position measurement method according to claim 2,
wherein the conditions are for the beam position, a multi-charged particle beam is divided by a plurality of regions, the mark is scanned with each of the regions, and a beam array shape of the multi-charged particle beam is calculated based on the corrected beam irradiation position.

5. The beam position measurement method according to claim 4,
wherein the reference condition is presence of one or a plurality of on-beams located in a center of the multi-charged particle beam.

6. The beam position measurement method according to claim 2,
wherein the conditions are for deflection voltage applied to a deflector, and a deflection sensitivity of the charged particle beam is calculated using the corrected beam irradiation position with a plurality of different deflection voltages.

7. The beam position measurement method according to claim 6,
wherein in the reference condition, the deflection voltage applied to the deflector is set to zero.

8. A charged particle beam writing method,
wherein an irradiation condition for the multi-charged particle beam is corrected based on a beam array shape calculated by the beam position measurement method according to claim 4, and a pattern is written on the substrate.
